(19) United States
(12) Patent Application Publication
(10) Pub. No.: US 2026/0371480 A1
(43) Pub. Date: Nov. 19, 2026

(54) THERMALLY CONDUCTIVE POLYIMIDE FILM, METHOD FOR PRODUCING THE SAME, METAL LAMINATE, ELECTRIC/ELECTRONIC DEVICE, AND FLEXIBLE PRINTED CIRCUIT BOARD

(71) Applicant: KANEKA CORPORATION, Osaka (JP)

(72) Inventor: Kan Fujiwara, Shiga (JP)

(73) Assignee: KANEKA CORPORATION, Osaka (JP)

(21) Appl. No.: 19/673,222

(22) Filed: May 11, 2026

(30) Foreign Application Priority Data
May 13, 2025 (JP) 2025-080508

(51) Int. Cl. H05K 1/03; H05K 3/00

(52) U.S. Cl. CPC H05K 1/0346; H05K 3/0064; H05K 2201/0154; H05K 2201/05; H05K 2203/0759

(57) ABSTRACT

A thermally conductive polyimide film having a small orientation anisotropy in the film width direction and high tensile elongation, a method for producing the polyimide film, a metal laminate including the polyimide film, electric/electronic device, and flexible printed circuit board are provided. The thermally conductive polyimide film includes boron nitride particles having an average particle diameter (D50) of 0.1 μm or more and 1 μm or less measured by dynamic light scattering method at a ratio of 30 wt % or more and 50 wt % or less. The thermally conductive polyimide film is continuously produced, and has a thermal conductivity of 0.7 W/mK or more in a thickness direction and 5 W/mK or more in an in-plane direction. The thermally conductive polyimide film has a tensile elongation rate of 50% or more, and average degree of molecular orientation in an entire film width of 1.01 or more and 1.30 or less.

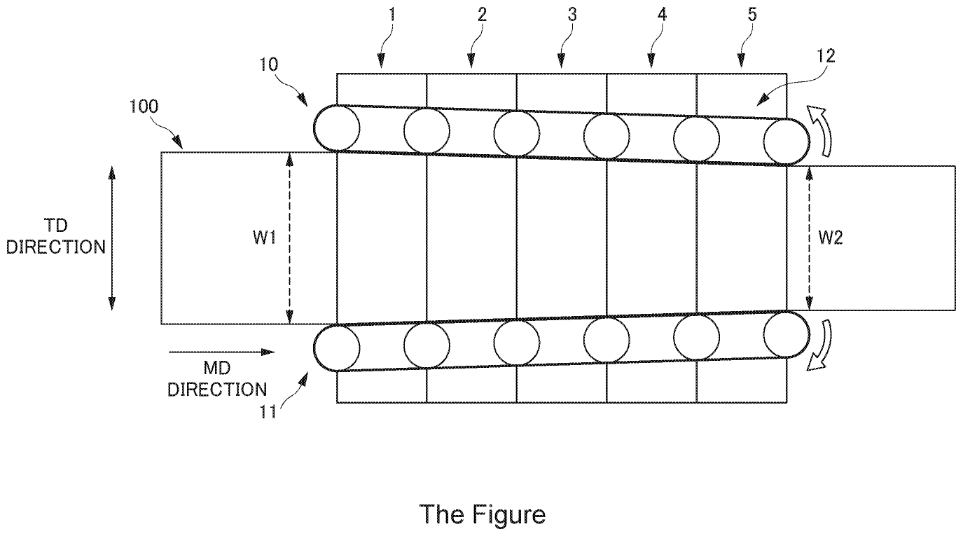

This application is based on and claims the benefit of priority from Japanese Patent Application No. 2025-080508, filed on 13 May 2025, the content of which is incorporated herein by reference.

### BACKGROUND

One or more embodiments of the present invention relate to a thermally conductive polyimide film, a method for producing the same, a metal laminate, an electric/electronic device, and a flexible printed circuit board.

In recent years, there has been an increasing demand for downsizing and weight reduction of electronic devices typified by mobile phones. Therefore, a flexible printed circuit board, which is advantageous for downsizing and weight reduction of electronic devices, has been widely used in the field of electronic technology. Among them, flexible printed circuit boards using a polyimide film as an insulating layer have been widely used conventionally because of their excellent heat resistance, chemical resistance, and the like. Recently, as an amount of calculation processing in an integrated circuit is improved accompanied by an improvement in connection speed and calculation speed, an amount of heat generation has increased, resulting in an increase in an amount of heat generation per unit area. On the other hand, because downsizing of electronic devices has also increased a degree of integration of circuits, heat transfer rate of a metal circuit for transferring the heat generated to heat dissipation devices (heat sink, thermal pad, and the like) is insufficient. Therefore, a heat dissipation means for releasing heat generated in the devices has been attracting attention in conjunction with high-speed information processing.

In order to provide a flexible printed circuit board excellent in heat dissipation, heat dissipation from a polyimide film which constitutes the insulating layer is required, in addition to heat dissipation from a metal circuit having high thermal conductivity. In other words, an improvement in thermal conductivity of the polyimide film is required.

As a method of improving the thermal conductivity of a polyimide film, a method of using a polyimide film containing, for example, a large amount of a highly thermally conductive inorganic filler is known (Patent Documents 1 and 2).

As a method for continuously producing a polyimide film, there is known, for example, a method in which an organic solvent solution of polyamic acid as a precursor is cast and applied onto a rotating support such as a metal drum and the obtained film is dried and cured until it becomes self-supportive. The obtained film is peeled off and conveyed to a tenter heating furnace while holding both ends of the film and maintaining or widening the width of the gel film, and the resulting film is further heated to dry and cure the film (Patent Document 3).
Patent Document 1: Japanese Unexamined Patent Application Publication No. 2012-176619
Patent Document 2: PCT International Publication No. WO 2011/111684
Patent Document 3: Japanese Unexamined Patent Application Publication No. 2008-012776

However, when a polyimide film containing a large amount of a highly thermally conductive inorganic filler is produced by the method described in Patent Document 3, orientation anisotropy in the width direction of the film tends to increase, and tensile elongation of the obtained polyimide film cannot be said to be sufficient.

### SUMMARY

One or more embodiments of the present invention have been made in view of the above, and to provide a thermally conductive polyimide film having a small orientation anisotropy in the width direction of the film and having a high tensile elongation, a method for producing the same, a metal laminate using the polyimide film, an electric/electronic device, and a flexible printed circuit board.

The present inventors have found that the above can be addressed by reducing a distance between fixing jigs for fixing both end portions in the width direction of the gel film to a specific range in the tenter heating step, and have completed one or more embodiments of the present invention.

Aspects of the present disclosure relate to the following thermally conductive polyimide film, a method for producing the same, a metal laminate, an electric/electronic device, and a flexible printed circuit board.

A first aspect of the present disclosure relates to a thermally conductive polyimide film including boron nitride particles having an average particle diameter (D50) of 0.1 μm or more and 1 μm or less measured by a dynamic light scattering method at a ratio of 30% by weight or more and 50% by weight or less, the thermally conductive polyimide film being continuously produced and having a thermal conductivity in a thickness direction of 0.7 W/mK or more, a thermal conductivity in an in-plane direction of the film of 5 W/mK or more, a tensile elongation rate of 50% or more, and an average degree of molecular orientation of the entire width of the film of 1.01 or more and 1.30 or less.

A second aspect of the present disclosure relates to the thermally conductive polyimide film as described in the first aspect, in which a polyimide resin of the thermally conductive polyimide film as described in the first aspect is a polymerization product of monomers including 25 to 75 mol % of biphenyltetracarboxylic dianhydride, 25 to 75 mol % of pyromellitic dianhydride, 0 to 80 mol % of paraphenylenediamine, and 20 to 100 mol % of 4,4′-diaminodiphenyl ether.

A third aspect of the present disclosure relates to a method for continuously producing a thermally conductive polyimide film, including:
step 1: obtaining a polyamic acid-containing mixture (I) including boron nitride particles and polyamic acid,
step 2: mixing the polyamic acid-containing mixture (I) with an imidization catalyst and/or a dehydration reagent to obtain a polyamic acid-containing mixture (II),
step 3: applying the polyamic acid-containing mixture (II) onto a support,
step 4: forming a gel film having self-supporting properties by drying the coating film obtained by the step 3,
step 5: peeling the gel film from the support, and
step 6: a tenter heating step of conveying and heating the gel film in a heating furnace while fixing both end portions of the peeled gel film in the width direction with fixing jigs without sag,
in which, in the step 6, W2/W1 is 0.80 or more and less than 1.00, where W1 refers to a distance between the fixing jigs immediately before entering the heating furnace and W2 refers to the shortest distance between the fixing jigs in the inside of the heating furnace and at the outlet of the heating furnace.

A fourth aspect of the present disclosure relates to a metal laminate including: the thermally conductive polyimide film as described in the first or second aspect and at least one metal layer laminated on one or both surfaces of the thermally conductive polyimide film.

A fifth aspect of the present disclosure relates to an electric/electronic device using the thermally conductive polyimide film as described in the first or second aspect.

A sixth aspect of the present disclosure relates to a flexible printed circuit board using the metal laminate as described in the fourth aspect.

According to one or more embodiments of the present invention, it is possible to provide a thermally conductive polyimide film having a small orientation anisotropy in the width direction of the film and having a high tensile elongation, a method for producing the same, a metal laminate using the polyimide film, an electric/electronic device, and a flexible printed circuit board.

### BRIEF DESCRIPTION OF THE DRAWING

The FIGURE is a schematic explanatory view showing an example of a tenter heating step according to one or more embodiments of the present invention.

### DETAILED DESCRIPTION

### <<Thermally Conductive Polyimide Film>>

The thermally conductive polyimide film is a continuously produced thermally conductive polyimide film, including boron nitride particles having an average particle diameter (D50) of 0.1 μm or more and 1 μm or less, as measured by a dynamic light scattering method, at a ratio of 30% by weight or more and 50% by weight or less.

The thermally conductive polyimide film has a thermal conductivity of 0.7 W/mK or more in the thickness direction, a thermal conductivity of 5 W/mK or more in the in-plane direction of the film, a tensile elongation rate of 50% or more, and an average degree of molecular orientation of 1.01 or more and 1.30 or less in the entire width of the film.

By producing the polyimide film by the method described below, the thermally conductive polyimide film has a small orientation anisotropy in the width direction of the film and a high tensile elongation.

Hereinafter, essential or optional components included in the thermally conductive polyimide film will be described.

### <Polyimide Resin (A)>

The polyimide resin (A) is a matrix resin of a thermally conductive polyimide film. The polyimide resin (A) is obtained by imidizing polyamic acid (C) using a known means for imidization. As the polyamic acid (C), which is a polyimide precursor, a polyamic acid acid solution is generally used. The concentration of the polyamic acid solution is not particularly limited and may be usually 5 mass % or more and 35 mass % or less, or 10 mass % or more and 30 mass % or less. When the concentration is in this range, the polyamic acid (C) having an appropriate molecular weight and solution viscosity can be obtained.

As a typical method of adding a monomer in the polymerization of the polyamic acid (C), the following method can be exemplified: 1) a method in which diamine is dissolved in an organic solvent (D) and reacted with a substantially equimolar amount of tetracarboxylic dianhydride to polymerize them; 2) a method in which tetracarboxylic dianhydride and a diamine compound in a slightly excess molar amount with respect to the tetracarboxylic acid dianhydride are reacted in an organic solvent (D) to obtain a prepolymer having an acid anhydride group at both ends; subsequently, polymerization is performed using diamine so that the tetracarboxylic acid dianhydride and the diamine are substantially equimolar in all the steps; 3) a method of reacting tetracarboxylic acid dianhydride and diamine in an excess molar amount with respect to the tetracarboxylic acid dianhydride in an organic solvent (D) to obtain a prepolymer having amino groups at both ends; subsequently, after the diamine is added thereto, polymerization is performed using the tetracarboxylic acid dianhydride so that the tetracarboxylic acid dianhydride and the diamine are substantially equimolar in all the steps; 4) a method in which tetracarboxylic acid dianhydride is dissolved or dispersed in an organic solvent (D) and then polymerization is performed using diamine so that the tetracarboxylic acid dianhydride and the diamine are substantially equimolar; and 5) a method in which a mixture of substantially equimolar amounts of tetracarboxylic acid dianhydride and diamine is reacted in an organic solvent (D). These methods may be used alone or may be used partially combined.

The order of addition of diamine and tetracarboxylic dianhydride as raw materials is not particularly limited, but the properties of the obtained polyamic acid or polyimide can be controlled not only by controlling the chemical structure of the raw materials but also by controlling the order of addition.

The term “substantially equimolar” as used herein means that when A mol of tetracarboxylic dianhydride and B mol of diamine are used, the reaction is performed in such a manner that a molar ratio calculated by A/B is within a range of 0.90 or more and 1.10 or less. In particular, controlling the molar ratio to 0.95 or more and 1.05 or less is preferable because the molecular weight of the polyamic acid (C) can be improved.

In order to control the reaction temperature, the polymerization may be performed in a reactor equipped with a temperature control device, and the temperature in the reaction solution may be 0 °C or higher and 60 °C or lower, or 15 °C or higher and 50 °C or lower.

For this production of the polyamic acid (C), a polyamic acid solution may be produced by performing the polymerization reaction in a single stage using a single reaction apparatus. In order to perform the polymerization reaction in a single stage, it is preferable to provide a step of dissolving the monomers in an organic solvent immediately before adding the monomers to the reaction vessel and removing contaminants with a filter or the like, in order to remove an undissolved raw material from the monomer components in the polymerization reaction and/or contaminants, thereby reducing the contaminants and/or defects in the film. Alternatively, it is preferable to perform the polymerization reaction after reducing contaminants and/or defects in the film by providing a step of directly sieving the powder to directly remove the contaminants. The pore size of the filter may be generally ½, ⅕, or 1/10 of the thickness of the film to be obtained. This is because defects caused by the undissolved raw material or contaminants present on the surface of the polyimide film decrease adhesion between the film and a metal layer in the step of forming a metal layer on the polyimide film.

Further, as another method, there is a method in which the polymerization reaction is performed in two stages. In this method, a low-viscosity polyamic acid called a prepolymer is polymerized in the first step, and then an organic solvent in which an acid dianhydride is dissolved is added to obtain a high-viscosity polyamic acid. When shifting from the first stage to the second stage, it is preferable to reduce the contaminants and/or defect in the prepolymer by providing a step of removing an undissolved raw material and/or contaminants in the prepolymer using a filter or the like. The pore size of the filter may be generally ½, ⅕, or 1/10 of the thickness of the film to be obtained. This is because defects caused by the undissolved raw material or contaminants present on the surface of the polyimide film decrease adhesion between the film and a metal layer in the step of forming the metal layer on the polyimide film.

### (Diamines)

Examples of the diamines include o-phenylenediamine, m-phenylenediamine, p-phenylenediamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, bis(4-amino-3,5-dimethylphenyl) methane, bis(4-amino-3,5-diisopropylphenyl) methane, 3,3′-diaminodiphenyldifluoromethane, 3,4′-diaminodiphenyldifluoromethane, 4,4′-diaminodiphenyldifluoromethane, 3,3′-diaminodiphenyl sulfone, 3,4′-diaminodiphenyl sulfone, 4,4′-diaminodiphenyl sulfone, 3,3′-diaminodiphenyl sulfide, 3,4′-diaminodiphenyl sulfide, 4,4′-diaminodiphenyl sulfide, 3,3′-diaminodiphenylketone, 3,4′-diaminodiphenylketone, 4,4′-diaminodiphenylketone, 2,2-bis(3-aminophenyl) propane, 2,2′-(3,4′-diaminodiphenyl) propane, 2,2-bis(4-aminophenyl) propane, 2,2-bis(3-aminophenyl) hexafluoropropane, 2,2-(3,4′-diaminodiphenyl) hexafluoropropane, 2,2-bis(4-aminophenyl) hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bisaniline, 3,4′-(1,4-phenylenebis(1-methylethylidene))bisaniline, 4,4′-(1,4-phenylenebis(1-methylethylidene))bisaniline, 2,2-bis(4-(3-aminophenoxy)phenyl) propane, 2,2-bis(4-(3-aminophenoxy)phenyl) hexafluoropropane, 2,2-bis(4-(4-aminophenoxy)phenyl) hexafluoropropane, bis(4-(3-aminoenoxy)phenyl) sulfide, bis(4-(4-aminoenoxy)phenyl) sulfide, bis(4-(3-aminoenoxy)phenyl) sulfone, bis(4-(4-aminoenoxy)phenyl) sulfone, aromatic diamines such as 3,5-diaminobenzoic acid, 1,3-bis(aminomethyl)cyclohexane, 2,2-bis(4-aminophenoxyphenyl) propane, 3,3′-dichlorobenzidine, 4,4′-diaminodiphenyl sulfide, 3,3′-diaminodiphenyl sulfone, 1,5-diaminonaphthalene, 2,2′-dimethoxy-4,4′-biphenyldiamine, 2,2′-dimethyl-4,4′-biphenyldiamine, 3,3′-dimethylbenzidine, 3,3′-dimethoxybenzidine, 4,4′-diaminodiphenyl propane, 2,4-bis(β-amino-t-butyl) toluene, bis(p-β-amino-t-butylphenyl) ether, bis(p-β-methyl-δ-aminophenyl)benzene, bis-p-(1,1-dimethyl-5-amino-pentyl)benzene, 1-isopropyl-2,4-m-phenylenediamine, m-xylylenediamine, p-xylylenediamine, di(p-aminocyclohexyl) methane, hexamethylenediamine, heptamethylenediamine, octamethylenediamine, nonamethylenediamine, decamethylenediamine, diaminopropyltetramethylene, 3-methylheptamethylenediamine, 4,4-dimethylheptamethylenediamine, 2,11-diaminododecane, 1,2-bis-3-aminopropoxy ethane, 2,2-dimethylpropylenediamine, 3-methoxyhexamethylenediamine, 2,5-dimethylheptamethylenediamine, 3-methylheptamethylenediamine, 5-methylnonamethylenediamine, 2,11-diaminododecane, 2,17-diaminoeicosadecane, 1,4-diaminocyclohexane, 1,10-diamino-1,10-dimethyldecane, 1,12-diaminooctadecane, and 2,2-bis[4-(4-aminophenoxy)phenyl]propane. These may be used alone or in combination of two or more types thereof. Among these, p-phenylenediamine, 4,4′-diaminodiphenyl ether, 2,2′-dimethyl-4,4′-biphenyldiamine, and 2,2-bis[4-(4-aminophenoxy)phenyl]propane are preferable.

### (Acid Dianhydrides)

Examples of the tetracarboxylic dianhydrides include pyromellitic dianhydride, 3,3′,4,4′-biphenyltetracarboxylic dianhydride, 2,2′,3,3′-biphenyltetracarboxylic dianhydride, 2,2-bis(3,4-dicarboxyphenyl) propane dianhydride, 2,2-bis(2,3-dicarboxyphenyl) propane dianhydride, 1,1-bis(2,3-dicarboxyphenyl) ethane dianhydride, 1,1-bis(3,4-dicarboxyphenyl) ethane dianhydride, bis(2,3-dicarboxyphenyl) methane dianhydride, bis(3,4-dicarboxyphenyl) methane dianhydride, bis(3,4-dicarboxyphenyl) sulfone dianhydride, 3,4,9,10-perylenetetracarboxylic dianhydride, bis(3,4-dicarboxyphenyl) ether dianhydride, benzene-1,2,3,4-tetracarboxylic dianhydride, 3,4,3′,4′-benzophenonetetracarboxylic dianhydride, 2,3,2′,3′-benzophenonetetracarboxylic dianhydride, 3,3,3′,4′-benzophenone tetracarboxylic dianhydride, 1,2,5,6-naphthalene tetracarboxylic dianhydride, 1,4,5,8-naphthalene tetracarboxylic dianhydride, 2,3,6,7-naphthalene tetracarboxylic dianhydride, 1,2,4,5-naphthalene tetracarboxylic dianhydride, 2,6-dichloronaphthalene-1,4,5,8-tetracarboxylic dianhydride, 2,7-dichloronaphthalene-1,4,5,8-tetracarboxylic dianhydride, 2,3,6,7-tetrachloronaphthalene-1,4,5,8-tetracarboxylic dianhydride, phenanthrene-1,8,9,10-tetracarboxylic dianhydride, pyrazine-2,3,5,6-tetracarboxylic dianhydride, thiophene-2,3,5,6-tetracarboxylic dianhydride, 2,3,3′,4′-biphenyltetracarboxylic dianhydride, 3,4,3′,4′-biphenyltetracarboxylic dianhydride, 2,3,2′,3′-biphenyltetracarboxylic dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylene bis(trimellitic anhydride), ethylene tetracarboxylic dianhydride, 1,2,3,4-butanetetracarboxylic dianhydride, decahydronaphthalene-1,4,5,8-tetracarboxylic dianhydride, 4,8-dimethyl-1,2,3,5,6,7-hexahydronaphthalene-1,2,5,6-tetracarboxylic dianhydride, cyclopentane-1,2,3,4-tetracarboxylic dianhydride, pyrrolidine-2,3,4,5-tetracarboxylic dianhydride, 1,2,3,4-cyclobutanetetracarboxylic dianhydride, bis(exo-bicyclo[2,2,1]heptane-2,3-dicarboxylic dianhydride, bicyclo-[2,2,2]-oct-7-ene-2,3,5,6-tetracarboxylic dianhydride, 2,2-bis(3,4-dicarboxyphenyl) propane dianhydride, 2,2-bis[4-(3,4-dicarboxyphenyl)phenyl]propane dianhydride, 2,2-bis(3,4-dicarboxyphenyl) hexafluoropropane dianhydride, 2,2-bis[4-(3,4-dicarboxyphenyl)phenyl]hexafluoropropane dianhydride, 4,4′-bis(3,4-dicarboxyphenoxy)diphenylsulfide dianhydride, 1,4-bis(2-hydroxyhexafluoroisopropyl)benzenebis(trimellitic anhydride), 1,3-bis(2-hydroxyhexafluoroisopropyl)benzenebis(trimellitic anhydride), 5-(2,5-dioxotetrahydrofuryl)-3-methyl-3-cyclohexene-1,2-dicarboxylic dianhydride, tetrahydrofuran-2,3,4,5-tetracarboxylic dianhydride, 1,2-(ethylene)bis(trimellitic anhydride), 1,3-(trimethylene)bis(trimellitic anhydride), 1,4-(tetramethylene)bis(trimellitic anhydride), 1,5-(pentamethylene)bis(trimellitic anhydride), 1,6-(hexamethylene)bis(trimellitic anhydride), 1,7-(heptamethylene)bis(trimellitic anhydride), 1,8-(octamethylene)bis(trimellitic anhydride), 1,9-(nonamethylene)bis(trimellitic anhydride), 1,10-(decamethylene)bis(trimellitic anhydride), 1,12-(dodecamethylene)bis(trimellitic anhydride), 1,16-(hexadecamethylene)bis(trimellitic anhydride), and 1,18-(octadecamethylene)bis(trimellitic anhydride). These may be used alone or in combination of two or more types thereof. Among these, 3,3′,4,4′-biphenyltetracarboxylic dianhydride, pyromellitic dianhydride, and 3,3′,4,4′-benzophenonetetracarboxylic dianhydride are preferable.

The polyimide resin (A) may be a polymerization product of monomers including 25 to 75 mol % of biphenyltetracarboxylic dianhydride and 25 to 75 mol % of pyromellitic dianhydride in all tetracarboxylic dianhydrides, and 0 to 80 mol % of paraphenylenediamine and 20 to 100 mol % of 4,4′-diaminodiphenyl ether in all diamines from the viewpoint of enhancing thermal conductivity and improving mechanical properties.

### (Organic Solvent (D))

The organic solvent (D) may be an organic polar solvent. The organic polar solvent is not particularly limited, but is required to be capable of dissolving polyamic acid without reacting with diamine or acid dianhydride. Examples of such organic polar solvents include 1-methylpyrrolidone, N, N-dimethylformamide, N, N-diethylformamide, N, N-dimethylacetamide, N-methyl-2-pyrrolidone, 1,3-dimethyl-2-imidazolidinone, 3-methoxy-N, N-dimethylpropanamide, and 3-methoxy-N, N-dibutylpropanamide. These may be used alone or in combination of two or more types thereof.

### (Imidization)

Polyimide is obtained by a dehydration conversion reaction (dehydration ring-closing reaction) from polyamic acid. As a method of performing the conversion reaction, two methods are widely known: a thermal curing method in which the conversion reaction is performed only by heat and a chemical curing method in which an imidization catalyst and a dehydration reagent are used. In order to improve the thermal conductivity, it is desired to use a thermal curing method. Furthermore, in order to promote thermal imidization, an imidization catalyst in combination with a polyamic acid precursor may be used, because the mechanical strength of the film can be ensured. In addition, the chemical curing method using an imidization catalyst and a dehydration reagent improves productivity and can secure mechanical strength of the film. In this case, a dehydration reagent and an imidization catalyst may be added to the polyimide precursor solution immediately before film formation.

### (Imidization Catalyst)

The imidization catalyst is a component having an effect of promoting a dehydration ring closure action on polyamic acid. As the imidization catalyst, for example, an aliphatic tertiary amine, an aromatic tertiary amine, or a heterocyclic tertiary amine can be used. Among them, nitrogen-containing heterocyclic compounds such as triethylamine, pyridine, imidazole, benzimidazole, isoquinoline, quinoline, lutidine, and pyridine compounds having an alkyl group substituted at the B-position and/or the y-position are preferable. In particular, pyridine, isoquinoline, imidazole, and pyridine compounds having an alkyl group substituted at the β-position and/or the y-position are preferable. More specifically, one or more imidization catalysts selected from isoquinoline, B-picoline, 3,5-lutidine, 1,2-dimethylimidazole, 2-ethyl-4-methylimidazole, 4-ethyl-2-methylimidazole, and 1-methyl-4-ethylimidazole may be used.

The content of the imidization catalyst relative to the polyamic acid depends on the structural formula constituting the polyamic acid, but the number of moles of the imidization catalyst/the number of moles of the amide group in the polyamic acid may be 10 to 0.01, or 5 to 0.1.

### (Dehydration Reagents)

The dehydration reagent is a dehydration ring closure agent for polyamic acid. As the dehydration ring closure agent, for example, an aliphatic acid anhydride, an aromatic acid anhydride, an N,N′-dialkylcarbodiimide, a lower aliphatic halide, a halogenated lower aliphatic acid anhydride, an arylsulfonic acid dihalide, a thionyl halide, or a mixture of two or more thereof can be used. Among these, an aliphatic acid anhydride and an aromatic acid anhydride work better, such as acetic anhydride.

The content of the dehydration reagent relative to the polyamic acid depends on the structural formula constituting the polyamic acid, but the number of moles of the dehydration reagent/the number of moles of the amide group in the polyamic acid may be 10 to 0.01, or 5 to 0.5. In this case, a reaction retarder such as acetylacetone may be used in combination.

### <Boron Nitride Particles (B)>

The shape of boron nitride particles (B) is not particularly limited, and may be, for example, spherical, plate-like, or a needle-like.

The particle diameter of boron nitride particles (B) may be 0.1 μm or more and 1 μm or less, 0.2 μm or more and 1 μm or less, 0.3 μm or more and 1 μm or less, or 0.4 μm or more and 1 μm or less. Particles having a particle diameter of 0.1 μm or more and 1 μm or less may be used because such particles can be easily dispersed uniformly in the inside of the polyimide film, increasing the probability of contact between the particles and improving the thermal conductivity. Furthermore, use of such particles is preferable, because their improved dispersibility within the resin can enhance the toughness of the resulting polyimide film. The particle diameter in one or more embodiments of the present invention is an average particle diameter (D50) measured by a dynamic light scattering method.

The content of the boron nitride particles (B) may be 30% by weight or more and 50% by weight or less, 33% by weight or more and 50% by weight or less, 36% by weight or more and 50% by weight or less, or 39% by weight or more and 48% by weight or less with respect to 100% by weight of the thermally conductive polyimide film.

### (Other Components)

The thermally conductive polyimide film may include a component (hereinafter, also referred to as “another component”) other than the polyimide resin (A) or the boron nitride particles (B) as long as the effect of one or more embodiments of the present invention is not impaired. As the other component, for example, an antioxidant, a light stabilizer, a flame retardant, an antistatic agent, a heat stabilizer, an ultraviolet absorber, an inorganic filler, a metal fine powder, or various reinforcing agents may be added. These other components may be used alone or in combination of two or more types.

The thickness of the thermally conductive polyimide film is not particularly limited, and may be appropriately set in a range of 10 μm or more and 200 μm or less. The width of the thermally conductive polyimide film is not particularly limited, and may be generally set appropriately in a range of 100 mm or more and 2,000 mm or less.

### <<Method for Producing Thermally Conductive Polyimide Film>>

Hereinafter, a method for producing the above-described thermally conductive polyimide film will be described.

The method for producing the thermally conductive polyimide film is a method for continuously producing a thermally conductive polyimide film, including:
step 1: obtaining a polyamic acid-containing mixture (I) including the boron nitride particles (B) and the polyamic acid (C),
step 2: mixing the polyamic acid-containing mixture (I) with an imidization catalyst and/or a dehydration reagent to obtain a polyamic acid-containing mixture (II),
step 3: applying the polyamic acid-containing mixture (II) onto a support,
step 4: forming a gel film having self-supporting properties by drying the coating film obtained by the step 3,
step 5: peeling the gel film from the support, and
step 6: a tenter heating step of conveying and heating the gel film in a heating furnace while fixing both end portions of the peeled gel film in the width direction with fixing jigs without sag.

In the step 6, W2/W1 is 0.80 or more and less than 1.00, where W1 is a distance between the fixing jigs immediately before entering the heating furnace and W2 is the shortest distance between the fixing jigs in the inside of the heating furnace and at the outlet of the heating furnace.

In the step 6, by setting W2/W1 to 0.80 or more and less than 1.00, it is possible to obtain a conductive polyimide film having a small orientation anisotropy in the width direction of the film and a high tensile elongation.

In the method for producing a thermally conductive polyimide film, “continuously producing” refers to production of a long thermally conductive polyimide film. The term “continuously producing” also includes one or more embodiments where roll-form thermally conductive polyimide films are produced by winding long films, from the viewpoint of improving yield, production stability, etc., during the mass production of flexible printed laminated plates.

### (Steps 1 and 2)

The step 1 is a step of obtaining a polyamic acid-containing mixture (I) containing boron nitride particles (B) and polyamic acid (C). The step 2 is a step of mixing the polyamic acid-containing mixture (I) obtained in the step 1 with an imidization catalyst and/or a dehydration reagent to obtain a polyamic acid-containing mixture (II).

The boron nitride particles (B), the polyamic acid (C), the imidization catalyst, and the dehydration reagent used in the step 1 and the step 2 are the same as the boron nitride particles (B), the polyamic acid (C), the imidization catalyst, and the dehydration reagent described in the item “Thermally Conductive Polyimide Film” above.

The polyamic acid-containing mixture (I) in the step 1 and the polyamic acid-containing mixture (II) in the step 2 may be prepared by mixing or dispersing the above-described components by a standard method using the organic solvent (D), in addition to the components described above. Examples of an apparatus that can be used for mixing or dispersing the above components include a dissolver, a homogenizer, a roll mill, a bead mill, a planetary mixer, a disper, a high-pressure jet disperser, and an ultrasonic disperser. After the above components are uniformly mixed, the resulting mixture may be further filtered using a mesh, a membrane filter, or the like.

### (Step 3)

The step 3 is a step of applying the polyamic acid-containing mixture (II) obtained in the step 2 onto a support. The polyamic acid-containing mixture (II) may be continuously applied onto the support.

As the support, any support can be used as long as it does not dissolve in the polyamic acid-containing mixture (II) and can withstand heating required for removing the organic solvent of the polyamic acid-containing mixture (II). The support may be an endless belt or a drum formed by joining metal plates, from the viewpoint of drying the coating liquid in the solution state. As a material of the endless belt or the drum, a metal may be used, and among them, an SUS material may be used.

### (Step 4)

The step 4 is a step of drying the coating film obtained in the step 3 to form a gel film having self-supporting properties.

The drying method may be hot air drying or radiation heat drying. The drying temperature may be 50 °C or higher and 200 °C or lower, or 100 °C or higher and 150 °C or lower. The drying time may be 1 minute or more and 30 minutes or less, or 5 minutes or more and 20 minutes or less.

The gel film refers to a polyimide precursor film in which a portion of the organic solvent remains in the polymer film after the polyamic acid-containing mixture (II) has been heated and dried.

### (Step 5)

The step 5 is a step of peeling the gel film obtained in the step 4 from the support.

### (Step 6)

The step 6 is a tenter heating step of fixing both end portions in the width direction of the peeled gel film obtained in the step 5 with fixing jigs without sag, and conveying and heating the gel film in a heating furnace. Examples of the fixing jig include a pin sheet and a clip.

In the step 6, W2/W1 may be 0.80 or more and less than 1.00, 0.85 or more and 0.99 or less, or 0.90 or more and 0.99 or less, where W1 is a distance between the fixing jigs in the film width direction (TD direction) immediately before entering the heating furnace and W2 is the shortest distance between the fixing jigs in the film width direction (TD direction) in the inside of the heating furnace and at the outlet of the heating furnace. By setting W2/W1 within the above range, it is possible to obtain a thermally conductive polyimide film having small orientation anisotropy in the width direction of the film and high tensile elongation. That is, in the step 6, after the gel film enters the heating furnace, the distance between the fixing jigs is narrowed in the inside of the heating furnace and at the outlet of the heating furnace. In the step 6, it is preferable to gradually (i.e., continuously) or stepwise narrow the distance between the fixing jigs to the outlet of the heating furnace. It is preferable that the distance between the fixing jigs is not increased after the distance between the fixing jigs is narrowed. Hereinafter, W2/W1 is also referred to as a “shrinkage ratio”.

The heating furnace may be a hot-air furnace of a type that injects hot air at temperatures ranging from 100 °C to 600 °C onto the entire film from the upper surface, the lower surface, or both surfaces. Alternatively, a far-infrared furnace may be equipped with a far-infrared emitter, allowing the film to be baked by far-infrared irradiation. In the step 6, it is preferable to gradually or stepwise increase the temperature from 100 °C to 600 °C, and therefore, it is preferable to use a hot-air furnace or a far-infrared furnace, or a stepwise heating furnace including both several hot-air furnaces and several far-infrared furnaces connected to each other, allowing the film to be heated. A partition device may be installed between each furnace to prevent the heat from transferring from the preceding furnace to the subsequent one.

In the step 6, the heating temperature applied first when the gel film is fixed and conveyed into the furnace may be 100 °C or higher and 250 °C or lower, or 120 °C or higher and 200 °C or lower. Specifically, the heating furnace may include two or more heating furnaces, and the temperature of the first heating furnace may be 100 °C or higher and 250 °C or lower.

The FIGURE is a schematic explanatory view showing an example of the step 6. The FIGURE shows a state in which both ends in the TD direction of a long gel film 100 obtained in the step 5 are fixed by fixing jigs 10 and 11, and the film is conveyed from the first heating furnace 1 to the fifth heating furnace 5 by a pin sheet rail 12 on a pin sheet (not shown) for conveying the film. First, both ends of the gel film 100 in the TD direction are fixed without sag by the distance W1 between the fixing jigs 10 and 11, the distance between the fixing jigs 10 and 11 is continuously narrowed in the heating furnaces 1 to 5, and the distance between the fixing jigs 10 and 11 is set to W2 at the outlet of the fifth heating furnace 5. Once the gel film 100 is conveyed to the heating furnaces 1 to 5, the gel film 100 is baked stepwise to proceed imidization.

The polyimide film obtained in the step 6 may be cooled slowly, and then the fixing jigs at both ends are removed to obtain a polyimide film.

### <Physical Properties of Thermally Conductive Polyimide Film>

### (Thermal Conductivity)

The thermal conductivity in the thickness direction of the thermally conductive polyimide film may be 0.70 W/mK or more, or 0.73 W/mK or more, from the viewpoint of suitable use as a flexible printed circuit board. The thermal conductivity of the thermally conductive polyimide film in the film in-plane direction may be 5.0 W/mK or more, or 6.0 W/mK or more, from the viewpoint of suitable use as a flexible printed circuit board.

The thermal conductivity in the thickness direction of the film is measured using a resin material thermal resistance measuring apparatus. The in-plane thermal conductivity of the film is measured using a thermowave analyzer.

### (Tensile Modulus of Elasticity)

The tensile modulus of elasticity of the thermally conductive polyimide film may be 1.5 GPa or more from the viewpoint of suitable use as a flexible printed circuit board or a heat dissipation member.

The tensile modulus of elasticity is measured according to ASTM-D882.

### (Tensile Elongation Rate)

The tensile elongation rate of the thermally conductive polyimide film may be 50% or more, 60% or more, or 70% or more, from the viewpoint of suitable use as a flexible printed circuit board or a heat dissipation member.

The tensile elongation rate is measured according to ASTM-D882.

### (Average Degree of Molecular Orientation)

The average degree of molecular orientation of the entire width of the thermally conductive polyimide film may be 1.01 or more and 1.30 or less, 1.02 or more and 1.25 or less, or 1.05 or more and 1.20 or less, from the viewpoint of small orientation anisotropy in the width direction of the film.

The average degree of molecular orientation is obtained by measuring degrees of orientation at both end portions in the width direction and at the central portion of the thermally conductive polyimide film, using a microwave molecular orientation meter, and calculating the average value thereof.

### <Application of Thermally Conductive Polyimide Film>

As described above, the thermally conductive polyimide film has a high elongation rate. Therefore, it can be suitably used as a flexible printed circuit board, a heat dissipation member, a metal laminate, an electric/electronic device, a magnet wire for motors, and an insulation-covered electric wire for flat cables.

### <<Metal Laminate>>

The metal laminate of one or more embodiments includes the thermally conductive polyimide film described above and
at least one metal layer laminated on one or both surfaces of the thermally conductive polyimide film.

The method of forming a metal laminate is not particularly limited, and examples thereof include the following method:
a metal layer to serve as an underlayer is directly formed on the surface of a thermally conductive polyimide film using a PVD method, and the resulting metal laminated plate is subjected to copper sulfate electroplating, whereby it is possible to prepare a metal laminate where a metal layer is laminated on the surface of the polyimide film, without using an adhesive. Here, the PVD method refers to various metal deposition methods such as a vacuum heating deposition method, an electron ion beam deposition method (EB deposition method), an ion plating method, a sputtering method, a plasma ion deposition method, and a CVD method.

As the metal serving as an underlayer, a noble metal, an alkaline earth metal, a transition metal (for example, copper, cobalt, nickel, chromium, titanium, or the like), or alloys of these metals may be used.

Further, the metal laminate in one or more embodiments of the present invention may be a metal laminated plate where a polyimide film is bonded to a metal foil via an adhesive. The above-described metal laminated plate can be suitably used for electric/electronic devices such as a flexible wiring board, a COF base film, a TAB tape, and a base film for high-density recording media.

As the adhesive, for example, an epoxy resin, a polyamide resin, a phenol resin, an acrylic resin, a polyimide resin, or a rubber resin may be used alone. Alternatively, a mixture obtained by mixing two or more of the above resins in various mixing ratios, together with a solvent, and adding an additive such as a curing agent or a curing accelerator, where needed, may be used.

### <<Insulation-Covered Electric Wire>>

The insulation-covered electric wire of one or more embodiments is an insulation-covered electric wire in which the above-described thermally conductive polyimide film is thermally fused to a metal conductor composed of metallic copper in the form of a coil or a flat cable through an adhesive selected from a fluorine-based resin material, a meta-aramid resin, a silicone resin, and the like each having thermal fusibility.

### EXAMPLES

Hereinafter, one or more embodiments of the present invention will be described more specifically based on Examples and Comparative Examples, but the present invention is not limited to the following Examples.

In the Examples and Comparative Examples, abbreviations of raw materials and solvents used for preparing a polyamic acid solution and the like are shown below.
DMF: N, N-dimethylformamide
ODA: 4,4′-diaminodiphenyl ether
p-PDA: paraphenylenediamine
BPDA: 3,3′,4,4′-biphenyltetracarboxylic dianhydride
PMDA: pyromellitic dianhydride

In the Examples and Comparative Examples, the following B1 was used as the boron nitride particles.
B1: boron nitride (D50: 0.9 μm in particle size distribution measurement using a particle size distribution analyzer (Microtrac MT3300 EXII, manufactured by MicrotracBEL Corporation))

### <Preparation of Thermally Conductive Polyimide Film>

### Examples 1 to 5 and Comparative Examples 1 and 2

### Example 1

744 kg of DMF was placed into a reactor, 52.88 kg of ODA and 7.14 kg of p-PDA were placed and dissolved, and 48.56 kg of BPDA and 36.00 kg of PMDA were added in this order in this ratio to polymerize, synthesizing a polyamic acid solution. To the polyamic acid solution, 102.95 kg of B1 and 330 kg of DMF were added and finely dispersed while heating to 50 °C to prepare a boron nitride dispersed polyamic acid solution (BN dispersed PA solution).

To 70 kg of this BN dispersed PA solution (total solid content of boron nitride and polyamic acid: 13.11 kg), 1.33 kg of isoquinoline, 0.066 kg of 1,2-dimethylimidazole, and 2.76 kg of DMF were added, and the resulting mixture was cast on an endless belt having a width of 500 mm so as to have a thickness of 40 μm. Thereafter, the resulting film was dried by hot air at a temperature in the range of 100 to 150 °C for 10 minutes to obtain a self-supporting gel film (polyimide precursor film).

The gel film was peeled off from the endless belt, and both ends in the width direction were fixed to a pin sheet, which continuously conveys the film, by a pin width of 350 mm without sag. Using the heating furnace according to the embodiment shown in the FIGURE, the gel film was baked stepwise in a first heating furnace (160 °C), a second heating furnace (200 °C), a third heating furnace (250 °C), a fourth heating furnace (300 °C), and a fifth heating furnace (380 °C), allowing the gel film to be imidized. The film was then peeled off at the outlet of the final furnace and the pin-sheet-fixing portions at the edges were slit to obtain a polyimide film with a width of 300 mm. The pin width was gradually narrowed in the furnaces, and at the outlet of the final furnace the pin width was 340 mm and the shrinkage ratio W2/W1 was 0.97. The content of the filler B1 in this study was 42% by weight.

### Examples 2 to 5 and Comparative Examples 1 and 2

Polyimide films of Examples 2 to 5 and Comparative Examples 1 and 2 were obtained in the same manner as in Example 1, except that the B1 was mixed with the polyamic acid solution at the content ratios shown in Table 1, and the shrinkage ratios W2/W1 were controlled to the values shown in Table 1.

### <Evaluation>

With respect to the polyimide films of Examples 1 to 5 and Comparative Examples 1 and 2 thus obtained, the thermal conductivity in the thickness direction, the thermal conductivity in the in-plane direction of the film, the tensile modulus of elasticity, the tensile elongation, and the average degree of molecular orientation were measured in accordance with the following methods. The results are shown in Table 1.

### (Thermal Conductivity in Thickness Direction)

A sample of 10 mm×10 mm was cut out from each polyimide film, and the thermal conductivity was determined using a resin material thermal resistance measuring device manufactured by Hitachi Technology and Services Ltd. at a time point when the thermal resistance value became constant at a sample temperature of 50 °C and a pressure of 50 N/cm².

### (Thermal Conductivity in In-Plane Direction of Film)

A sample measuring 20 mm×30 mm was cut out from each polyimide film using a Thermowave Analyzer TA3 manufactured by Bethel and measurement was conducted to obtain thermal diffusivity under the following conditions: frequency: 0.25 Hz; distance range: start 0.5 mm to end 2.0 mm; distance interval: 0.33 mm; laser output: 1%; a number of measurements: 1, and sampling interval: 3.0 sec. The thermal conductivity was then calculated using the following physical properties: boron nitride: specific heat of 810 J/kgK and density of 2.27 g/cm³, and polyimide resin: specific heat of 1,130 J/kgK and density of 1.4 g/cm³.

### (Tensile Modulus of Elasticity and Tensile Elongation)

A test piece (5 mm×100 mm) was cut out from each polyimide film. Each sample was measured according to ASTM-D882 using a tensile tester (Autograph S-100-C) manufactured by Shimadzu Corporation.

### (Average Degree of Molecular Orientation)

Degrees of orientation of both end portions and the center portion of each polyimide film were measured with a molecular orientation meter (manufactured by Oji Scientific Instruments, trade name: MOA6015), and the average value was calculated to use as the average degree of molecular orientation.

TABLE 1

| | | | | | | | Comparative | Comparative |
|---|---|---|---|---|---|---|---|---|
| | | Example 1 | Example 2 | Example 3 | Example 4 | Example 5 | Example 1 | Example 2 |
| Content of boron | wt% | 42 | 43 | 43 | 45 | 42 | 43 | 25 |
| nitride particles | | | | | | | | |
| Shrinkage ratio W2/W1 | — | 0.970 | 0.947 | 0.950 | 0.917 | 0.947 | 1.100 | 1.050 |
| Thermal conductivity in | W/mK | 0.75 | 0.71 | 0.79 | 0.73 | 0.74 | 0.68 | 0.59 |
| the thickness direction | | | | | | | | |
| Thermal conductivity in | W/mK | 5.9 | 7.7 | 7.3 | 6.3 | 6.8 | 4.8 | 4.8 |
| the in-plane direction | | | | | | | | |
| Tensile modulus of | GPa | 1.9 | 2.2 | 2.2 | 1.6 | 2.1 | 2.8 | 1.8 |
| elasticity | | | | | | | | |
| Tensile elongation | % | 82 | 64 | 89 | 59 | 97 | 15 | 40 |
| Average degree of | — | 1.12 | 1.07 | 1.11 | 1.11 | 1.03 | 1.31 | 1.34 |
| molecular orientation | | | | | | | | |

From the results of Table 1, it can be seen that the thermally conductive polyimide films of Examples 1 to 5 containing 30 wt % or more of boron nitride particles and having W2/W1 of less than 1.00 had a smaller orientation anisotropy in the width direction of the film and a higher tensile elongation, compared to the thermally conductive polyimide film of Comparative Example 1, which had W2/W1 exceeding 1.00, or the thermally conductive polyimide film of Comparative Example 2, which contained 25 wt % of boron nitride particles and had W2/W1 exceeding 1.00.

EXPLANATION OF REFERENCE NUMERALS

| | |
|---|---|
| 1 | First heating furnace |
| 2 | Second heating furnace |
| 3 | Third heating furnace |
| 4 | Fourth heating furnace |
| 5 | Fifth heating furnace |
| 10 | Fixing jig |
| 11 | Fixing jig |
| 12 | Pin sheet rail |
| 100 | Gel film |

Although the disclosure has been described with respect to only a limited number of embodiments, those skilled in the art, having benefit of this disclosure, will appreciate that various other embodiments may be devised without departing from the scope of the present disclosure. Accordingly, the scope of one or more embodiments of the invention should be limited only by the attached claims.

What is claimed is:

1. A thermally conductive polyimide film comprising:
boron nitride particles having an average particle diameter (D50) of 0.1 μm or more and 1 μm or less,
wherein:
the average particle diameter of the boron nitride is measured by a dynamic light scattering method at a ratio of 30% by weight or more and 50% by weight or less,
the thermally conductive polyimide film is a continuously produced film, and
the thermally conductive polyimide film has:
a thermal conductivity in a thickness direction of 0.7 W/mK or more,
a thermal conductivity in an in-plane direction of the film of 5 W/mK or more,
a tensile elongation rate of 50% or more, and
an average degree of molecular orientation of an entire width of the film of 1.01 or more and 1.30 or less.

2. The thermally conductive polyimide film according to claim 1, wherein a polyimide e resin of the thermally conductive polyimide film is a polymerization product of monomers comprising:
25 to 75 mol % of biphenyltetracarboxylic dianhydride,
25 to 75 mol % of pyromellitic dianhydride,
0 to 80 mol % of paraphenylenediamine, and
20 to 100 mol % of 4,4′-diaminodiphenyl ether.

3. A method for continuously producing a thermally conductive polyimide film, comprising:
obtaining a polyamic acid-containing mixture (I) comprising boron nitride particles and polyamic acid,
mixing the polyamic acid-containing mixture (I) with an imidization catalyst and/or a dehydration reagent to obtain a polyamic acid-containing mixture (II),
applying the polyamic acid-containing mixture (II) onto a support to produce a coated film,
forming a gel film having self-supporting properties by drying the coated film obtained by the applying,
peeling the gel film from the support, and
a tenter heating step of conveying and heating the gel film in a heating furnace while fixing both end portions of the peeled gel film in a width direction with fixing jigs without sag,
wherein in the tenter heating, W2/W1 is 0.80 or more and less than 1.00,
where:
W1 is a distance between the fixing jigs immediately before entering the heating furnace, and
W2 is a shortest distance between the fixing jigs in an inside of the heating furnace and at an outlet of the heating furnace.

4. A metal laminate comprising:
the thermally conductive polyimide film according to claim 1, and
at least one metal layer laminated on one or both surfaces of the thermally conductive polyimide film.

5. An electric/electronic device comprising the thermally conductive polyimide film according to claim 1.

6. A flexible printed circuit board comprising the metal laminate according to claim 4.

7. A metal laminate comprising:
the thermally conductive polyimide film according to claim 2, and
at least one metal layer laminated on one or both surfaces of the thermally conductive polyimide film.

8. An electric/electronic device comprising the thermally conductive polyimide film according to claim 2.

9. A flexible printed circuit board comprising the metal laminate according to claim 7.
